(19) United States
(12) Patent Application Publication
(10) Pub. No.: US 2009/0283136 A1
(43) Pub. Date: Nov. 19, 2009

(54) Panel Form Photovoltaic Frameless Solar Module

(76) Inventors: Markus Münch, Coswig (DE); Michael Janker, Dresden (DE)

Correspondence Address: Horst M. Kasper, 13 Forest Drive, Warren, NJ, 07059, US

(21) Appl. No.: 12/085,918

(22) PCT Filed: Nov. 30, 2006
(86) PCT No.: PCT/DE2006/002117

§ 371 Date: May 30, 2008

(30) Foreign Application Priority Data
Nov. 30, 2005 (DE) 102005057468.8

(51) Int. Cl. H01L 31/048

(52) U.S. Cl. 136/251

(57) ABSTRACT

The invention relates to a panel form photovoltaic frameless solar module, in particular, a large surface solar module having increased stability and strength. The aim of the invention is to produce the panel form photovoltaic solar module which is insensitive to rough climatic effects of the weather as well as effective at diffusing very high mechanical stresses in the substructure. A planar light weight reinforcement structure (5) is at least partially stuck directly to the reverse side of the material (4), for planar or curved solar modules, in the inventive panel form photovoltaic frameless solar module (1) which comprise solar cells (3), which are embedded between cover side of the material (2) and the reverse side of the material (4). Said light weight reinforcement structure (5) is embodied entirely or partially on at least two sides as a supporting frame structure (6), that is additionally reinforced. The invention can be used for commercial, panel form solar modules, in particular, for thin-walled solar module embodiments, like those produced, in particular, in glass-film-laminates.

The invention relates to a photovoltaic frameless solar module in panel form, in particular a large area covering solar module with increased stability and strength according to the preamble of the main claim.

A photovoltaic solar module (PV-module) has a flat, planar or slightly curved structure into which the solar cells are embedded. This flat structure protects the solar cells both against the rough climatic influences, as well as against the different mechanical influences. Only therewith the mounting on roofs, free areas and elsewhere becomes possible. Solar cells are today employed at about 95 percent as solar cells of crystalline silicon. However also cells out of amorphous silicon and thin layer cells are applied for special applications because of the small requirements in semiconductor material.

The embedded solar cells, inclusive the connections of the individual solar cells amongst each other and in particular the soldering connections at the connection points are sensitive against mechanical loads, weather influences and humidity. The solar cells become larger and larger. Thus increasingly already solar cells of 150 mm times 150 mm and larger are employed. Typically they are embedded in a transparent compound material and are preferably fixed between two glass plates or other rigid materials and are therewith simultaneously protected. The upper covering can also comprise another transparent material, were as it is known to furnish the lower coverings out of different possible materials such as in particular sheet metal, plastic plates or plastic foils. The performance with the glass plate on the front side and a foil on the rear side (glass—foil—laminate) is usual practice and is offered in most standard photovoltaic modules by many producers. Since the glass-foil-laminates have clearly a smaller support capacity in contrast to the glass-glass-laminates, usually frames out of aluminum continuous casting profiles are placed for reinforcement. According to a market survey published in the year 2004 by the German society for solar energy (Deutsche Gesellschaft fuer Sonnenenergie e. V.), of the framed photovoltaic modules a part of 97 percent is taken by those with a frame out of an aluminum extruder profile. The balance is taken by frames out of stainless-steel, plastic and polymer concrete, which however are employed only for reinforcing smaller photovoltaic modules for special purposes such as for example roof covering elements or vehicular roof hatch spaces. Two other solutions are described in the literature, there the reinforcement of the photovoltaic modules has been realized by a trapezoidal sheet metal adhesively attached to the rear side.

It is common to all aluminum frames that the connection to the photovoltaic module is realized by plugging into a groove of the profile and additional gluing and/or screwing. The mounting on roofs of a framed photovoltaic module is conceivably simple, for example it can be effected by clamping. The predominantly circulating line shaped capturing and support of the photovoltaic module is disadvantageous with this kind of framing. With larger and larger dimensions of the photovoltaic module also the bending through in the middle becomes stronger. Thus the conventional kind of framing opposes the trend to larger and larger photovoltaic modules which are more cost-efficient.

The projecting edge of the frame above the photovoltaic module's plane represents a further disadvantage. Increasing soiling in the region of this circulating projecting edge are the consequence, which again decreases the energy yield. The sliding off of snow and the self purification by rainwater is rendered more difficult through this projecting so-called dirt edge. These disadvantageous effects occur to be more clearly visible the lesser the photovoltaic module is inclined in the incorporated state.

The European patent EP 1 146 297 A1 is concerned with the problem of the self purification with a frame which is edge free on one side. Herewith is negative the fixation of the incorporation position through the manufacturer. The sliding off of snow and the support capability remain furthermore deficient, since still projecting edges above the glass plane are present relative to the complete so-called photovoltaic generator (coupling of several photovoltaic modules).

The petit patent German Gebrauchsmuster DE 202 15 462 U1 describes a frame form part with support elements for the receiving of a photovoltaic module. The flat like reinforcement affects positively on the support capacity and a soiling edge is not formed. The mounting is however only on adhesively attachable bases possible, which requirement opposes a use as a standard photovoltaic module for all cases of applications.

The solution according to German patent document DE 36 11 543 A1 describes a photovoltaic module, wherein a trapezoidal sheet metal is connected in the lamination process and through a melt adhesive to the laminate. The subject matter of the mounting is not considered and remains therefore unresolved.

According to a further German printed patent document DE 40 14 200 A1 there is described amongst others the adhesive attachment by the manufacturer of attachment profiles onto the rearside of the photovoltaic module in the edge region of the photovoltaic module. These attachment profiles from the German printed patent document DE 40 14 200 A1 serve for screwing onto a frame system. Here the edge formation of this attachment profile is formed such massive that the attachment of the solar module to the base is performed alone at the attachment profile. Simultaneously the area loads are received through these attachment profiles.

It is an object of the present invention to create a photovoltaic solar module in panel form, which is both insensitive toward the rough climatic weather influences, wherein the large thermal loads caused by shadow and sun irradiation do not produce damages in the electrical part as well as deflects very high mechanical loads into the sub construction.

This object is obtained according to the present invention by the features of the first claim. Further advantageous embodiments of the invention are subject matter of subclaims. According to the present invention a flat like light construction reinforcement structure 5 is disposed partially adhesively attached directly on the back side material 4 for planar or arched solar modules in connection with a photovoltaic frameless solar module 1 in panel form with solar cells 3 embedded between the cover side material 2 and the rearside material 4. The light construction reinforcement structure 5 is completely or partially at least two sides formed as a support frame structure 6, that is the light construction reinforcement structure 5 is additionally reinforced. In case of arched or curved solar modules, the light construction reinforcement structure 5 and the therewith connected support frame structure 6 are correspondingly convexly arched. It is also conceivable that the rear side material 4 is furnished with attachment projections or attachment slots, with which the light construction reinforcement structure 5 can be furnished mechanically connected to connection bolts or connection hooks.

According to a preferred embodiment the light construction reinforcement structure 5 and the support frame structure 6 can be furnished out of the same or out of different materials and can be disposed material fitting amongst them or shape matching amongst them.

The support frame structure 6.1 can be disposed as a completely separate construction part connected with the rear side material 4 of the flat like photovoltaic solar module 1 in panel form and with the light weight construction reinforcement structure 5.

Preferably the photovoltaic frameless solar module 1 in panel form according to the present invention is dimensioned such that the light weight construction reinforcement structure 5 with the support frame structure 6 connected thereto projects over the outer dimensions of the solar module 1 via a defined projection reaching outwardly and therewith a circulating projecting edge 8 is formed, wherein the projecting edge 8 enables a comprehensive edge protection.

It is also possible to form the support frame structure 6 as a closed support profile, that is for example formed out of a usual extruder profile of a suitable material such as light metal or plastic.

It is advantageous where especially formed grooves 9 are disposed in the support frame structure 6.1, wherein attachment elements corresponding to the shape of the grooves engage the especially formed grooves 9 and which attachment elements permanently fix the solar module 1, in particular for a quick and simple mounting of the photovoltaic frameless solar module 1 at the installation location.

In order to be able to accomplish a favorable cooling and a further weight reduction of the support frame structure 6, it is possible to furnish the support frame structure as an open support profile 6.2, that is furnished as a subdivided or with openings provided extruding profile.

It is particular effective where the flat like light construction reinforced structure 5 and the support frame structure 6 is formed out of an embossed, differently folded and angled light metal profile 10 in order to achieve high strength and stability of the arrangement of a solar module according to the present invention. This embodiment is much more stable than embodiments with smooth surfaces as is known from usual light weight metal sheet, in particular from aluminum sheet metal.

A particular stiffness with very small wall thickness can be achieved, if the flat like light construction reinforcement structure 5 and the support frame structure 6 are formed from an embossed honeycomb like light sheet metal structure.

An embodiment of the flat like light construction reinforcement structure 5 and the support frame structure 6 out of a wave or corrugated composite material can also achieve a required stiffness of the complete construction with minimum material deployment.

It is advantageous to form the flat like light construction reinforcement structure (5) and/or the support frame structure 6 out of a foamed light metal, such as for example foamed aluminum materials for extreme application situations for example in particular, in storm or hurricane endangered regions.

Further stability is also possible by forming the flat like light construction reinforcement structure 5 and support frame structure 6 out of embossed, differently folded and angled light metal profile 11 and again formed in itself singly or multiply folded and angled.

It can also be advantageous to form the flat like light construction reinforcement structure 5 and the support frame structure 6 from sandwich materials based on light metals and/or based on plastic and/or based on fiber reinforced plastic. In particular in the embodiment with suitable fiber reinforced materials a high stiffness with simultaneously optimized light weight construction is possible.

For a further stability increase it is advantageous if on the rear side of the light construction reinforcement structure 5 there is disposed an additional connected reinforcement material 7, such as for example a foil adhesively attached to the rear side.

The same effect can be obtained if instead of a closed compound material 7 a reinforcement material 7.1 formed as a grid or as a fixed net 12 is disposed connected point wise with the light construction reinforcement structure 5. The strength properties here remain unchanged relative to the closed embodiment, while the rear side nevertheless can be surrounded by a flow of cooling air.

Cross struts and/or longitudinal braces can be disposed also in the interior of the flat like light construction reinforcement structure 5 for improving the stability of a photovoltaic frameless solar module 1 in panel form.

The solution according to the present invention is also suitable for bent photovoltaic frameless solar modules 1, since the flat like light construction reinforcement structure 5 and the support frame structure 6 can also be furnished bent and thereby adapt to the convex arching of a bent solar module without leaving a gap and can be adhesively attached on the bent solar module.

It is possible to freely select the incorporation position locally with the photovoltaic solar module 1 in panel form according to the present invention. The surface of the solar module is very plane and homogeneous and has clearly improved properties, with regard to sliding off of snow and self purification and to a walking possibility on the solar module surface. Therewith it is also possible to ensure the required safety in storm or hurricane endangered regions despite a light construction embodiment. If nevertheless a breakage of a photovoltaic solar module in panel form should occur by way of extreme force interaction, then the breakage pieces are substantially secured against sliding off by the light construction reinforcement structure, or, respectively, less sharp edged breakage pieces can be generated.

The present invention enables on the one hand an essential weight reduction as compared with the known standard photovoltaic modules and on the other hand also mounting with known standardized mounting systems, such as for example by clamping connectors, by employing the flat like light construction reinforcement structure with the support frame structure. The novel photovoltaic frameless solar module has a multiply high support capacity as compared with up to now known frameless solar modules, wherein the possibly occurring pressure forces are advantageously distributed and can also be entered without problem into the below disposed attachment construction. A walking on the surface is possible without danger of breakage despite light construction. Also relatively large face embodiments of photovoltaic frameless solar modules 1 in panel form with solar cells 5 (translator's remark: should be 3) embedded between the cover side material 2 and the rear side material 4 for both planar or arched solar modules can be performed and also be mounted and repaired in a simple and time saving way. Finally the energy efficiency is therewith increased and the cost use ratio is further improved.

The invention is to be described in more detail in the following by way of the five figures in different embodiment examples.

FIG. 1 shows a cross section through a photovoltaic solar module 1 in panel form according to the present invention out of a planar panel subjectable to a pull load and to a pressure load, as well as solar cells 3 embedded between a cover side material 2, which preferably comprises glass and a rear side material 4, which preferably comprises a plastic foil, wherein the solar cells 3 have been applied for example in a laminating process. In accordance with the present invention a flat like light construction reinforcement structure 5 with filigree, resolved cross section is attached behind this solar module 1 out of the glass-film-laminate, wherein the light construction reinforcement structure 5 is arranged here in a flat adhesively attached compound. Based on the material fitting adhesively attaching of the rearside material 4 to the flat like light construction reinforcement structure 5, a substantially higher stability of this compound is achieved under the use of the proper stiffness of the two construction components. Based on the novel constructive embodiment whereby the light construction reinforcement structure 5 together with the therewith connected support frame structure 6 has a circulating projecting edge 8, there is generated a circulating edge protection with the advantages of a frameless embodiment in the region of the module plane. These advantages comprise that the snow can slide off very well and a self cleaning during rain is performed up to the outermost regions of the solar module surface. Since in particular the snow does not any longer attach that quickly, the construction according to the present invention leads to an overall higher energy yield in the winter time. The light construction reinforcement structure 5 is furnished toward the out side again reinforced as a support frame structure 6 according to the present invention. The reinforcements are shown in FIG. 1 at two sides in two variations. On the one hand it is possible that the support frame structure 6 is made out of a material of higher density or out of a different material as the further inwardly disposed light construction reinforcement structure 5 on the outside at the edge of the under-construction. The support frame structure 6.1 is made out of a different more stable material as the material of the light construction reinforcement structure 5 as shown by the right embodiment according to FIG. 1. Here this support frame structure 6.1 consists of a U-shaped extruded profile into which the light construction reinforcement structure 5 engages. Both materials can be connected only form matching or also material matching. Here both open profiles, such as U-, L-, T-, or double T-profiles, as well as also closed profiles such as rectangular or other boxed profiles can be employed. The use of this extremely thin-walled profile in the outer region under the solar module plane, coupled with the flat like reinforcement according to the present invention is in particular novel. This leads to the same effect as is otherwise only known alone with standard-wise employed solar modules with circulating over gripping frame construction out of aluminum extruder profiles. Also the solar module 1 furnished according to the present invention deflects, despite its substantially reduced weight, the pressure forces or, respectively, loads occurring during mounting and assembling on roofs or free surfaces reliably down into the under construction. The photovoltaic solar module 1 in panel form according to the present invention can be loaded without consideration by human beings for mounting purposes and for repair purposes. In addition it is possible to produce also area wise larger solar modules than hitherto usual, which reduces the installation costs for the installed KW-power. Overall the material use can be drastically reduced in contrast to usual constructions, wherewith also a far-reaching reduction of the weight can be achieved.

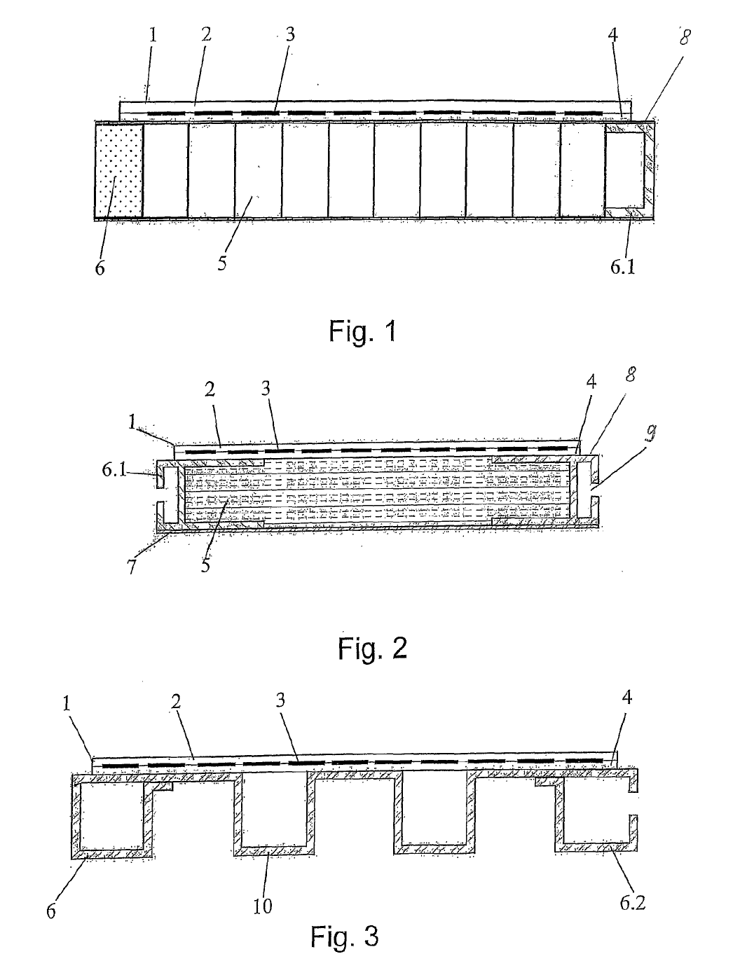

The light construction reinforcement structure 5 can be formed as visible in FIG. 2 as a sandwich plate with one side or two side cover layers and/or intermediate layers out of for example metal foils, impregnated paper, or fiber reinforced plastics, preferably light sheet metal (for example out of aluminum) and core materials preferably out of light metal honeycomb structures, however also out of paper honeycomb or Aramide honeycomb or chemically treated regrowing raw materials, such as for example vertically disposed cane tubelets or plastic tubelets, balsa weed or foamed materials. These materials are preferably integrated into the reinforced light construction structure of the support frame structure 6 in the outer region under the plane of the solar module. Also rectangular, trapezoidal or wave profiles consisting of for example metal or preferably light metal, fiber reinforced or not reinforced plastic faces can take the flat reinforcement. Here the edge profile can be formed in the forming process or can be disposed separately and can be attached. Also extruded aluminium, extruded plastic profiles or profiles from thermo wood can be arranged in the outer regions of the support frame structure 6 for better load deflection into the under construction.

A reinforced light construction structure of a support frame structure 6.1 is shown in FIG. 2, wherein specially formed extruder profiles out of light metal are disposed projecting far into the interior up to the region of the flat like layer like constructed light construction reinforcement structure for deflecting large loads into the sub construction. A specially formed groove 9 is in each case disposed in these on two sides equal extruded profiles of the support frame structure 6.1, wherein corresponding attachment elements according to the form of the grooves for mounting engage the specially formed groove 9 (not illustrated). The light construction reinforcement structure 5 with the therewith connected support frame structure 6 is constructed such that the light construction reinforcement structure 5 and the support frame structure 63 reach over the outer dimensions of the solar module 1 by a defined over stand. A circulating projecting edge 8 is thereby generated, wherein the edge 8 assures a comprehensive edge protection during transport and mounting.

FIG. 3 shows a cross-section through an embodiment of the flat like light construction reinforcement structure 5, material matching connected to the reinforced light construction structure of the support frame structure 6, as a construction out of an embossed, differently folded and angled light metal profile 10, here in an embodiment in a uniform, rectangular, folded and angled form. By having this embossed, differently folded and angled light metal profile in the region of the reinforced light construction structure of the support frame structure 6 such angled that a closed support frame structure 6 is generated, then here also the load deflection can be assured to a sufficient degree. It is shown on the right hand side that the support frame structure can also be furnished as a support profile 6.2 point wise broken out for better cooling purposes. These openings of the support profile 6.2 can serve also as attachment openings for the solar module according to the present invention, wherein attachment elements can engage in turn in the attachment openings.

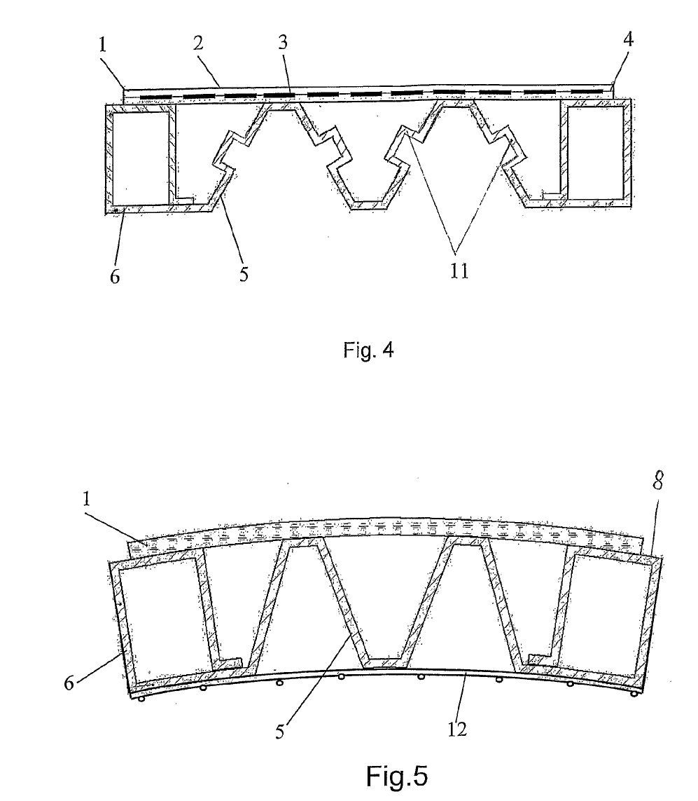

A similarly rendered solution as in FIG. 3 is shown in FIG. 4. However in this preferred embodiment the flat like light construction reinforcement structure 5 and the support frame structure 6 are formed from embossed, differently folded and angled light metal profile 11 and are in themselves again and another time multiply folded and angled. This is associated with the advantage that such construction can again increase the stiffness of the flat like light construction reinforcement structure 5 and the support frame structure 6. This is in particular an advantage were large area solar module structures are concerned. Here the bending through in the middle of the solar module upon load, for example during walking by a mounting person, can be reduced. Here an additional rectangular structure is shown. In the same way triangular or wave anglings can be performed with the same effect.

A possible special embodiment for a convex arched photovoltaic frameless solar module 1 in panel form is shown in FIG. 5 with solar cells 3 bendable within certain limits and embedded between the arched cover side material 2 and the arched rear side material 4, for application situations on a curved background. Here the arched light construction reinforcement structure 5 is also completely or partially at the support faces adhesively attached to the rear side material 4. The arched support frame structure 6 as above already described is disposed at longitudinal sides of the light construction reinforcement structure 5. Additional reinforcement material 7 in the shape of a grid or a solid net 12 and point wise connected to the light construction reinforcement structure 5 and disposed under the support frame structure 6 as well as under the flat like light construction reinforcement structure 5. A very high point wise area load not reachable by other constructions can occur without damages for the life time of the solar modules with the embedded solar cells 3 with this particular embodiment.

The invention can be employed for all commercially usual panel shape solar modules, in particular for thin walled solar module embodiments as are produced predominantly in connection with glass-foil-laminates.

### LIST OF REFERENCE CHARACTERS

1 photovoltaic solar module in panel form
2 cover side material
3 solar cells
4 rear side material
5 flat like light construction force and structure
6 support frame structure reinforced light construction structure
6.1 support frame structure as a separate construction part
6.2 support profile
7 reinforcement material
   8 circulating projecting edge
9 specially formed grooves
10 folded and angled aluminum profile
11 differently in themselves again single or multiple folded and angled aluminum sandwich profile
12 grid or solid net

1. Photovoltaic frameless solar module (1) in panel form with solar cells (3) embedded between cover side material (2) and rear side material (4) for planar or curved solar modules,
characterized in that
a flat like light construction reinforcement structure (5) is disposed on the rear side material (4) completely or partially adhesively attached to or connected, wherein the light construction reinforcement structure (5) completely or partially is performed as a support frame structure (6) at least two sides of the light construction reinforcement structure (5).

2. Photovoltaic frameless solar module (1) in panel form according to claim 1,
characterized in that
the light construction reinforcement structure (5) and the support frame structure (6) are furnished out of equal or different materials and are disposed connected to each other material matching or form matching.

3. Photovoltaic frameless solar module (1) in panel form according to claim 1,
characterized in that
a support frame (6.1) is disposed as a separate construction part connected with the rear side material (4) of the flat like photovoltaic solar module (1) and the light construction reinforcement structure (5).

4. Photovoltaic frameless solar module (1) in panel form according to claim 1,
characterized in that
the light construction reinforcement structure (5) together with the therewith connected support frame structure (6) is formed as a circulating projecting edge (8).

5. Photovoltaic frameless solar module (1) in panel form according to claim 1,
characterized in that
the support frame structure (6) is furnished as a closed support profile (extruder profile).

6. Photovoltaic frameless solar module (1) in panel form according to claim 1,
characterized in that
specially formed grooves (9) are disposed in the support frame structure (6.1), wherein attachment elements corresponding to the form of the grooves engage the grooves for mounting.

7. Photovoltaic frameless solar module (1) in panel form according to claim,
characterized in that
the support frame structure (6) is formed as an open support profile 6.2 as a subdivided or with openings furnished extruder profile.

8. Photovoltaic frameless solar module (1) in panel form according to claim 1,
characterized in that
the flat like light construction reinforcement structure (5) and the support frame structure (6) are formed of an embossed, differently folded and angled light metal profile (10).

9. Photovoltaic frameless solar module (1) of panel form according to claim 1,
characterized in that
the flat like light construction reinforcement structure (5) and the support frame structure (6) are formed out of an embossed honeycomb like light sheet metal structure.

10. Photovoltaic frameless solar module (1) in panel form according to claim 1,
characterized in that
the flat like light construction reinforcement structure (5) and the support frame structure (6) are formed out of a wave composite material.

11. Photovoltaic frameless solar module (1) in panel form according to claim 1,
characterized in that
the flat like light construction reinforcement structure (5) and/or the support frame structure (6) are formed out of a foamed light metal.

12. Photovoltaic frameless solar module (1) in panel form according to claim 8,
characterized in that
the flat like light construction reinforcement structure (5) and the support frame structure (6) are formed as embossed, differently folded and angled light metal profile (11) which is again in itself one or more times folded and angled.

13. Photovoltaic frameless solar module (1) in panel form according to claim 1,
characterized in that
the flat like light construction reinforcement structure (5) and the support frame structure (6) consists of sandwich materials on a light metal basis and/or plastic basis and/or fiber reinforced plastic materials.

14. Photovoltaic frameless solar module (1) in panel form according to claim 1,
characterized in that
a reinforcing material (7) is disposed on the rear side of the light construction reinforcement structure (5).

15. Photovoltaic frameless solar module (1) in panel form according to claim 1,
characterized in that
the reinforcing material (7) is formed in the shape of a grid or of a solid net (12) and is connected point wise with the light construction reinforcement structure (5).

16. Photovoltaic frameless solar module (1) in panel form according to claim 1,
characterized in that
cross and/or longitudinal braces are disposed in the interior of the flat like light construction reinforcement structure (5).

17. Photovoltaic frameless solar module (1) in panel form according to claim 1,
characterized in that
the flat like light construction reinforcement structure (5) and the support frame structure (6) are furnished bent and wherein a bent solar module (1) is disposed adhesively attached thereupon.
